(19) United States
(12) Patent Application Publication
(10) Pub. No.: US 2024/0186254 A1
(43) Pub. Date: Jun. 6, 2024

(54) CARRIER STRUCTURE SUITABLE FOR CHIPLET FINE LINE AND MANUFACTURING METHOD THEREOF, AND FINE LINE CHIPLET PACKAGING STRUCTURE AND MANUFACTURING METHOD OF THE SAME

(71) Applicant: INSTITUTE OF SEMICONDUCTORS, GUANGDONG ACADEMY OF SCIENCES, Guangzhou (CN)

(72) Inventors: Yunzhi LING, Guangzhou (CN); Yingqiang YAN, Guangzhou (CN); Xun XIANG, Guangzhou (CN); Chuan HU, Guangzhou (CN); Wei ZHAO, Guangzhou (CN); Zhitao CHEN, Guangzhou (CN)

(21) Appl. No.: 18/162,110

(22) Filed: Jan. 31, 2023

(30) Foreign Application Priority Data
Dec. 2, 2022 (CN) 202211533027.8

(51) Int. Cl. H01L 23/538; H01L 21/48; H01L 23/31; H01L 23/498

(52) U.S. Cl. CPC H01L 23/5383; H01L 21/4857; H01L 23/3185; H01L 23/49816

(57) ABSTRACT

Disclosed are a method for manufacturing a carrier structure suitable for chiplet fine lines and a carrier structure. The method includes: preparing a temporary bonding layer on a temporary carrier, and preparing a pin interconnection layer on the temporary bonding layer, preparing at least one fine line interconnection layer on the pin interconnection layer; preparing a core layer on the at least one fine line interconnection layer with a second electrically conductive structure interconnected with the at least one fine line interconnection layer and/or the pin interconnection layer, preparing at least one build-up layer connected to the fine line interconnection layer on the core layer, and de-bonding the temporary bonding layer to obtain the carrier structure. The solutions can prepare fine lines on a carrier structure and ensure the yield of fine line interconnection lines, thus improving the manufacturability of the fine lines, carrier structure and packaging structure.

### TECHNICAL FIELD

The present invention relates to the technical field of integrated circuit packaging, in particular to a carrier structure suitable for chiplet fine lines and a manufacturing method thereof, a fine line chiplet packaging structure and manufacturing method of the same.

### BACKGROUND

In semiconductor chip manufacturing, integrated circuit packaging is a back-end-of-line in chip manufacturing. In this process, it is often necessary to bond one or more integrated circuit chips/dies to a packaging carrier. The carrier can provide electrical contacts to one or more integrated circuit chips/dies bonded thereto, thereby enabling connection of the one or more integrated circuit chips/dies to one or more external devices. Up to now, various packaging methods have been developed in the prior art, among which 2.5D packaging has been developed into a mainstream advanced packaging technology oriented to high-end applications such as cloud computing, high-speed network, image processing, automatic driving and so on. because it can effectively reduce the size of the package and/or improve the integration of the package. “2.5D” refers to a packaging technology in which multiple chips/chiplets are integrated into the same package.

In the 2.5D packaging technology, the main packaging forms include interposer packaging, embedded silicon bridge packaging, and interposer-free packaging. Interposer-free packaging realizes the interconnection of one or more integrated circuit chips/dies through high-density RDL, and receives extensive attention due to its relatively low cost and thin package thickness obtained thereby. However, in order to achieve efficient interposer-free packaging, several major technical difficulties still need to be broken through, namely manufacturing of fine lines, warpage control of the packaging carrier, and mechanical strength control during a transfer process.

### SUMMARY OF THE INVENTION

Embodiments of the present invention provide an interposer-free packaging solution to solve at least one technical difficulty existing in the current interposer-free packaging technology.

In a first aspect, an embodiment of the present invention provides a method for manufacturing a carrier structure suitable for chiplet fine lines, including:
preparing a temporary bonding layer on a temporary carrier, and preparing a pin interconnection layer on the temporary bonding layer;
preparing at least one fine line interconnection layer on the pin interconnection layer;
preparing a core layer on the at least one fine line interconnection layer, wherein the core layer is formed with a second electrically conductive structure interconnected with the at least one fine line interconnection layer and/or the pin interconnection layer;
preparing at least one build-up layer connected to the fine line interconnection layer on the core layer, wherein BGA openings are formed in an outermost build-up layer; and
de-bonding the temporary bonding layer to obtain a carrier structure including the pin interconnection layer, the at least one fine line interconnection layer, the core layer, and the at least one build-up layer.

In a second aspect, an embodiment of the present invention provides a method for manufacturing a fine line chiplet packaging structure, including:
preparing the carrier structure including the pin interconnection layer, the at least one fine line interconnection layer, the core layer, and the at least one build-up layer by using the method described in the first aspect according to the embodiment of the present invention;
connecting a desired number of chips to the pin interconnection layer of the carrier structure;
preparing a plastic packaging protection layer on the chips; and
preparing BGA balls at BGA openings of the build-up layer of the carrier structure.

In a third aspect, an embodiment of the present invention provides a carrier structure suitable for chiplet fine lines, including
a pin interconnection layer;
at least one fine line interconnection layer disposed on a first side of the pin interconnection layer;
a core layer disposed on a side of the at least one fine line interconnection layer away from the pin interconnection layer, wherein a second electrically conductive structure is formed in the core layer, and the core layer is interconnected with the at least one fine line interconnection layer and/or the pin interconnection layer through the second electrically conductive structure; and
at least one build-up layer disposed on a side of the core layer away from the at least one fine line interconnection layer, wherein the at least one build-up layer is connected with the fine line interconnection layer through the second electrically conductive structure, and BGA openings are formed in an outermost build-up layer.

In a fourth aspect, an embodiment of the present invention provides a fine line chiplet packaging structure, including:
a pin interconnection layer;
at least one fine line interconnection layer disposed on a first side of the pin interconnection layer;
a core layer disposed on a side of the at least one fine line interconnection layer away from the pin interconnection layer, wherein a second electrically conductive structure is formed in the core layer, and the core layer is interconnected with the at least one fine line interconnection layer and/or the pin interconnection layer through the second electrically conductive structure;
at least one build-up layer disposed on a side of the core layer away from the at least one fine line interconnection layer, wherein the at least one build-up layer is connected with the fine line interconnection layer through the second electrically conductive structure, and BGA openings are formed in an outermost build-up layer;
at least one chip bonded to a second side of the pin interconnection layer;
a plastic packaging protection layer disposed on the chip; and
BGA balls disposed at the BGA openings.

In a fifth aspect, an embodiment of the present invention provides a carrier structure manufactured by using the method described in the first aspect of the embodiments of the present invention.

In a sixth aspect, an embodiment of the present invention provides a fine line chiplet packaging structure manufactured by using the method described in the second aspect of the embodiments of the present invention.

The embodiments of the present invention have the following beneficial effects. In the solution provided by the embodiments of the present invention, fine lines can be prepared in a carrier structure and a packaging structure, and all fine line structures are first prepared on a temporary carrier, so that fine line interconnection lines are fabricated on a smooth hard substrate, thereby ensuring the yield of the fine line interconnection lines and improving the manufacturability of the fine line structure. Furthermore, in this way, the line width and line spacing of fine lines can be manufactured as small as possible, thereby achieving RDL with higher density and improving the integration degree and integration efficiency of the prepared packaging structure. In addition, according to the solution of the embodiments of the present invention, a core layer is first prepared on a fine line interconnection layer, and then the fine line structure is transferred, which realizes accurate control of the mechanical strength of the fine line structure during a transfer process and in turn improves the reliability and manufacturability of the carrier structure and packaging structure. Moreover, a temporary bonding method is adopted to prepare the carrier structure, which avoids wrapping in the carrier structure.

### BRIEF DESCRIPTION OF THE DRAWINGS

In order to illustrate the technical solutions of the embodiments of the present disclosure more clearly, a brief description of the accompanying drawings used in the description of the embodiments will be given as follows. Obviously, the accompanying drawings are some embodiments of the present disclosure, and those skilled in the art can also obtain other drawings based on these drawings without any creative effort.

FIG. 1 schematically shows a vertical cross-sectional view of a carrier structure suitable for chiplet fine lines according to an embodiment of the present invention;

FIG. 2 schematically shows a flowchart of a method for manufacturing a carrier structure suitable for chiplet fine lines according to an embodiment of the present invention;

FIG. 3 schematically shows a vertical cross-sectional view of a carrier structure obtained after a pin interconnection layer is prepared on a temporary bonding layer according to an embodiment of the present invention;

FIG. 4 schematically shows a vertical cross-sectional view of a carrier structure obtained after a pin interconnection layer is prepared on a temporary bonding layer according to another embodiment of the present invention;

FIG. 5 schematically shows a vertical cross-sectional view of a carrier structure obtained after a fine line interconnection layer is prepared on the pin interconnection layer according to an embodiment of the present invention;

FIG. 6 schematically shows a vertical cross-sectional view of a carrier structure obtained after a fine line interconnection layer is prepared on the pin interconnection layer according to another embodiment of the present invention;

FIG. 7 schematically shows a vertical cross-sectional view of a carrier structure obtained after a core layer is prepared on the fine line interconnection layer according to an embodiment of the present invention;

FIG. 8 schematically shows an implementation flowchart of operation S23 in FIG. 2 according to an embodiment of the present invention;

FIG. 9 schematically shows a vertical cross-sectional view of a carrier structure obtained after a support substrate of the core layer is prepared on the fine line interconnection layer according to an embodiment of the present invention;

FIG. 10 schematically shows a vertical cross-sectional view of a carrier structure obtained after plastic vias are prepared on the support substrate according to an embodiment of the present invention;

FIG. 11 schematically shows a vertical cross-sectional view of a carrier structure obtained after a build-up layer is prepared on the core layer according to an embodiment of the present invention;

FIG. 12 schematically shows a vertical cross-sectional view of a carrier structure obtained after a build-up layer is prepared on the core layer according to another embodiment of the present invention;

FIG. 13 schematically shows a flowchart of a method for manufacturing a carrier structure suitable for chiplet fine lines according to another embodiment of the present invention;

FIG. 14 schematically shows a vertical cross-sectional view of a fine line chiplet packaging structure according to an embodiment of the present invention;

FIG. 15 schematically shows a vertical cross-sectional view of a fine line chiplet packaging structure according to another embodiment of the present invention;

FIG. 16 schematically shows a flowchart of a method for manufacturing a fine line chiplet packaging structure according to an embodiment of the present invention; and

FIG. 17 schematically shows a vertical cross-sectional view of a packaging structure obtained after a chip is connected to a carrier structure in some embodiments.

### DETAILED DESCRIPTION OF THE EMBODIMENTS

To make the objectives, technical solutions, and advantages of the embodiments of the present invention clearer, the technical solutions in the embodiments of the present invention will be described below with reference to the accompanying drawings in the embodiments of the present invention. Obviously, these embodiments are only some but not all of the embodiments of the present invention. Other embodiments that can be obtained by those skilled in the art without creative efforts based on the disclosed embodiments fall within the protection scope of the present invention.

It should be noted that the embodiments in the present invention and the features in these embodiments may be combined with each other when no conflict exists.

It should also be noted that generally the terms used in the present invention are those commonly used by the skilled in the art, and shall prevail when being inconsistent with commonly used ones.

Finally, it should also be noted that, wordings like first and second are merely for separating one entity or operation from the other, but not intended to require or imply a relation or sequence among these entities or operations. Further, it should be noted that in this specification, terms such as “comprised of” and “comprising” shall mean that not only those elements described thereafter, but also other elements not explicitly listed, or elements inherent to the described processes, methods, objects, or devices, are included. In the absence of specific restrictions, elements defined by the phrase “comprising . . . ” do not mean excluding other identical elements from process, method, article or device involving these mentioned elements. Finally, it should also be noted that relational terms such as first and second herein are only used to distinguish one entity or operation from another, and do not necessarily require or imply that any such actual relationship or sequence exists between these entities. It should be understood that the terms used in this way may be interchanged under appropriate circumstances, and thus are only for distinguishing objects of the same attribute in the description of the embodiments of the present invention. Moreover, the terms “comprise” and “comprising” not only include those elements, but also include other elements not explicitly listed, or also include elements inherent in such a process, method, article, or device. In the absence of further limitations, an element defined by the statement “comprising . . . ” does not exclude additional identical elements from process, method, article or device involving the mentioned elements. Those of ordinary skill in the art can understand the specific meanings of the above terms in the present invention according to specific context.

Herein, the term “chiplet” refers to a system-on-chip set formed by integrating and packaging chips or dies that meet specific functions through advanced packaging technology.

Herein, the term “chip” refers not only any type of semiconductor chip or integrated circuit chip that realizes a specific function, but also any type of semiconductor die or integrated circuit die that realizes a specific function.

Herein, the term “fine line” refers to an internal interconnection line in which a line width of a single line and spacing between two adjacent lines are both less than 10 um.

The assembly of individually designed computing units or functional units through advanced packaging technology can not only ensure the yield of each unit by selecting the most suitable semiconductor process technology for each unit, but also effectively reduce the design and manufacturing cost of chips and shorten the chip development cycle. Among them, the Die-to-Die internal interconnection technology is the key to realizing the integration and packaging of chips or dies that meet specific functions, and is the basis for realizing advanced packaging. Among various forms of advanced packaging technologies that have been developed, interposer-free packaging in 2.5D packaging has attracted widespread attention due to its low cost and thin package obtained thereby. In the interposer-free packaging technology, its internal interconnection is realized through high-density RDL (Redistribution Layer). Therefore, the yield of the internal interconnection lines, the line width, the line spacing and the like in the RDL are key to the reliability and manufacturability of the interposer-free packaging technology. Especially because the manufacturing of fine lines is difficult and the yield is difficult to be effectively guaranteed, it seriously affects the manufacturability of the interposer-free packaging technology. Based on this, an objective of the embodiments of the present invention is to provide a solution for interposer-free packaging technology suitable for chiplet fine lines, so as to improve the yield of fine lines, ensure the feasibility of the interposer-free packaging technology, and ensure the device reliability of the carrier structure and packaging structure based on the interposer-free packaging technology.

The solutions provided by the embodiments of the present invention will be described in detail below from the perspective of the configuration of the obtained carrier structure and packaging structure.

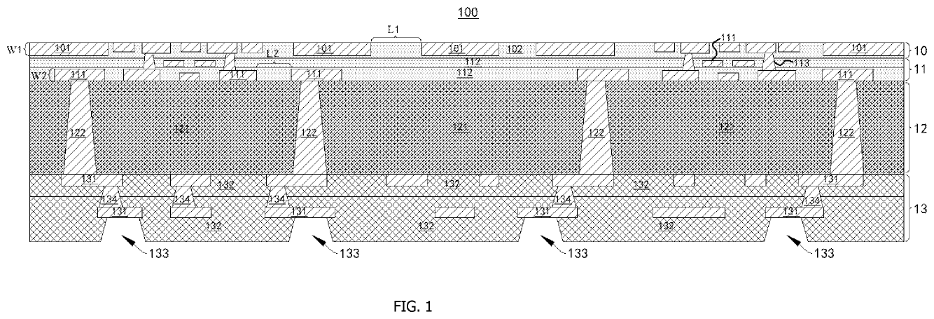

FIG. 1 schematically shows a vertical cross-sectional view of a carrier structure 100 according to an embodiment of the present invention. As shown in FIG. 1, the carrier structure 100 includes a pin interconnection layer 10, at least one fine line interconnection layer 11, a core layer 12, and at least one build-up layer 13, which realize electrical interconnection through a built-in internal interconnection structure being electrically conductive. As a possible embodiment, the electrical interconnection between the pin interconnection layer 10, the at least one fine line interconnection layer 11, the core layer 12, and the at least one build-up layer 13 in the carrier structure 100 may be exemplarily realized by designing conductive vias, conductive contacts and/or internal electrical interconnection lines in corresponding layers of the carrier structure 100.

In the carrier structure 100 of the embodiments of the invention, the pin interconnection layer 10 provides a connection interface between the carrier structure 100 and a chip to be integrated and packaged that realizes a specific function, while the other layers of the carrier structure 100 realize electrical connection with the above chip through the pin interconnection layer 10. It may be understood that the types and quantities of chips integrated on the carrier structure 100 may be selected based on needs. For example, the chips selected based on needs to be boned to the carrier structure 100 may be one or more chips with computing function or data transmission function, etc. Correspondingly, the number and types of the connection interfaces with the chip to be integrated and packaged that realizes a specific function, which are disposed on the pin interconnection layer 10, may also be designed according to requirements. For example, it may be designed according to the number of functional chips to be bonded and interface characteristics. In an exemplary embodiment, the chip bonded to the carrier structure 100 may specifically be a processor, a memory, a sensor, or a passive device and the like.

The fine line interconnection layer 11 in the carrier structure 100 is a redistribution layer (also known as RDL) of fine lines for providing electrical interconnection, which is the key to realizing the interposer-free packaging technology. By rewiring the fine lines and providing connection interfaces (also called contact positions or I/O contacts) for chips to be integrated and packaged based on the layout of the fine lines on this layer, it is possible to interconnect chips with different specific functions. Due to high process cost of 2.5D advanced packaging technology, it is currently mainly oriented to high-end applications with high-performance requirements, such as applications with high computing performance requirements, and such high-performance requirements also put forward more stringent requirements on the integration and performance of carrier structures. It is readily understandable that the integration and performance of the carrier structure are largely determined by the configuration (such as the line width and line spacing of the fine lines) and yield of the fine lines in the fine line interconnection layer. However, in the existing interposer-free packaging technology, the fine line structure normally needs to go through a process of fabrication and retransfer. In this preparation process, how to ensure the yield of the fine lines and make their line width and line spacing meet expectations to improve the integration and performance of the carrier structure 100 is an important technical problem to be solved urgently. In order to solve this technical problem, the carrier structure 100 of the embodiment of the present invention is also provided with a core layer 12, which is used to provide controllable mechanical strength support for the fine line interconnection layer 11 during the transfer process, so that the retransfer process of the fine line structure is reliable, thereby improving the implementability of the interposer-free packaging technology, ensuring the manufacturability of the fine line structure and improving the yield of the fine line structure.

The build-up layer 13 in the carrier structure 100 is used as a flip-chip structure of the carrier structure, so that an electrical signal of the fine line interconnection layer 11 can be drawn out on the build-up layer 13 in a flip-chip manner, and the carrier structure 100 can be electrically connected to external devices such as chip substrates and PCB boards through flip-chip packaging (Flip-Chip). At the same time, the build-up layer 13 may also be used as a heat dissipation structure of the carrier structure, so as to provide a heat dissipation function for the package using the carrier structure. In some embodiments, the build-up layer 13 may be at least one redistribution layer with I/O contacts or pin interfaces connected to external devices, with the fineness of the internal interconnection lines being lower than that of the fine line interconnection layer. In further embodiments, the build-up layer 13 may also be a substrate provided with a desired form and quantity of I/O contacts or pin interfaces connected with external devices. In the embodiment of the present invention, the electrical signal of the fine line interconnection layer 11 is drawn out through the core layer, so as to form a flip-chip/heat dissipation structure in the build-up layer on the other side of the core layer. In a possible embodiment, the fineness of the internal interconnection lines may be determined by a line width of a single line and a line spacing between two adjacent lines. Preferably, the fineness of the internal interconnection lines is negatively correlated with the line width of a single interconnection line and the line spacing between two adjacent interconnection lines. That is, the smaller the line width of a single interconnection line and the smaller the line spacing between two adjacent interconnection lines, the higher the fineness of the internal interconnection lines.

As an exemplary embodiment, as shown in FIG. 1, the fine line interconnection layer 11 in the carrier structure 100 is disposed on a first side of the pin interconnection layer 10, and a second side of the pin interconnection layer 10 facing away from the first side is used for bonding with a chip with a specific function to be integrated. The first side and the second side of the pin interconnection layer 10 refer to two opposite outer surfaces of the pin interconnection layer. The fine line interconnection layer 11 is disposed on the first side, and the second side is used for bonding with the chip to be integrated. The core layer 12 is disposed on a side of the fine line interconnection layer 11 away from the pin interconnection layer 10. Similarly, in order to more clearly distinguish two opposite outer surfaces of the fine line interconnection layer, in the embodiment of the present invention, an outer surface of the fine line interconnection layer 11 provided with the core layer 12 is referred to as a first side of the fine line interconnection layer 11, and an outer surface of the fine line interconnection layer 11 opposite to the first side and adjacent to the pin interconnection layer 10 is referred to as a second side of the fine line interconnection layer 11. The build-up layer 13 is disposed on a side of the core layer 12 away from the fine line interconnection layer. Similarly, in order to more clearly distinguish two opposite outer surfaces of the core layer 12, in the embodiment of the present invention, an outer surface of the core layer 12 provided with the build-up layer is referred to as a first side of the core layer 12, and an outer surface of the core layer 12 opposite to the first side and adjacent to the fine line interconnection layer is referred to as a second side of the core layer 12. One or more than two fine line interconnection layer 11 and build-up layer 13 may be provided as required. In an embodiment in which more than two fine line interconnection layers 11 are provided, the core layer 12 is disposed on the first side of the outermost fine line interconnection layer 11. The outermost layer is defined with respect to the direction of the pin interconnection layer, which points away from the pin interconnection layer. That is, the fine line interconnection layer adjacent to the pin interconnection layer is the innermost fine line interconnection layer.

In some possible embodiments, the pin interconnection layer 10 includes a plurality of first internal interconnection lines 101 being electrically conductive, the number of which may be set according to requirements. The first internal interconnection lines in the pin interconnection layer 10 are preferably interconnection lines made of a conductive material such as metal, preferably copper, silver or gold. In some embodiments, the pin interconnection layer 10 further includes a first insulating material 102 for providing electrical isolation between adjacent first internal interconnection lines 101 being electrically conductive. The first insulating material may be an organic material such as epoxy, BT, or polyimide. In some preferred embodiments, a line width W1 of each single first internal interconnection line is between 2-200 μm, and a line spacing L1 between any two adjacent first internal interconnection lines is between 2-200 μm. Within this range, the line width W1 of each prepared first internal interconnection line and the line spacing L1 between adjacent first internal interconnection lines may be set according to different application requirements, so that the first internal interconnection lines of the pin interconnection layer can be prepared as fine lines according to expectations and requirements.

In some possible embodiments, the fine line interconnection layer 11 includes a plurality of second internal interconnection lines 111 being electrically conductive and at least one first electrically conductive structure 113 being electrically conductive with the first internal interconnection lines of the pin interconnection layer 10. The number of the second internal interconnection lines, and the number and positions of the first electrically conductive structures may be set according to requirements. The second internal interconnection lines in the fine line interconnection layer 11 are preferably fine lines made of a conductive material such as metal, preferably copper, silver or gold. The first electrically conductive structures in the fine line interconnection layer 11 may be exemplarily contact points, conductive vias, or conductive columns. In some embodiments, the fine line interconnection layer 11 further includes a second insulating material 112 for providing electrical isolation between adjacent second internal interconnection lines being electrically conductive and/or first electrically conductive structures. The second insulating material may be an organic material such as epoxy resin, BT, or polyimide. In some preferred embodiments, a line width of each single second internal interconnection line in each fine line interconnection layer 11 is set between 0.1-10 μm, and a line spacing between any two adjacent second internal interconnection lines in the same fine line interconnection layer is also set between 0.1-10 μm. Within this range, the line width of each prepared second internal interconnection line and the line spacing between adjacent second internal interconnection lines in the same layer may be set according to different application requirements. In the embodiment of the present invention, the second internal interconnection lines provided in the fine line interconnection layer are all prepared as fine lines.

In some possible embodiments, the core layer 12 includes a support substrate 121 and at least one second electrically conductive structures 122 being electrically conductive with the first internal interconnection lines of the pin interconnection layer 10 and/or the second internal interconnection lines of the fine line interconnection layer 11. The number and positions of the second electrically conductive structures may be set according to requirements. The support substrate in the core layer 12 is used to regulate the mechanical strength of the prepared carrier structure and provide support for the fine line interconnection layer during the transfer process, so as to increase the yield and reliability of the prepared carrier structure and improve the manufacturability of the carrier structure. The thickness of the support substrate can characterize the internal stress and mechanical strength of the core layer, which in turn can affect the preparation yield of the fine line interconnection layer and reflect the mechanical strength and reliability of the prepared carrier structure. Therefore, in some possible embodiments, the thickness of the support substrate can be adjusted to meet the requirements of different application scenes, so as to take into account the mechanical strength of the carrier structure and the manufacturability of the fine lines under different application requirements and improve the manufacturability and reliability of the carrier structure. Specifically, in the embodiment of the present invention, the thickness of the support substrate is positively correlated with the mechanical strength of the prepared carrier structure and the manufacturing difficulty of the second internal interconnection lines in the fine line interconnection layer. That is, the thicker the support substrate, the thicker the prepared core layer, and accordingly, the higher the mechanical strength of the obtained carrier structure, while the more difficult to punch holes and manufacture the fine lines. Therefore, the thickness of the support substrate may be designed according to the requirements of the application scene for which the prepared carrier structure is applicable. Preferably, the thickness of the support substrate can be adjusted adaptively on demand within the range of 50-1000 μm, so as to take into account the manufacturability and yield of the fine lines on the basis of ensuring the overall mechanical strength of the carrier structure, and avoid difficulty in manufacturing the fine lines caused by the thickness of the support substrate, thereby manufacturing a carrier structure that meets the performance requirements of corresponding scenes. The second electrically conductive structures in the core layer 12 may be exemplarily conductive vias or conductive columns. The conductive vias may be, for example, vias disposed on the support substrate and coated with a conductive material such as metal. In other possible embodiments, the properties of the material used to prepare the support substrate may also be used to achieve the goal of controlling the yield of the fine line interconnection layer and the reliability of the carrier structure through the core layer. As a preferred embodiment, the CTE (thermal expansion coefficient) of the material used to prepare the support substrate may be used to achieve the goal of controlling the yield of the fine line interconnection layer and the reliability of the carrier structure through the core layer. Preferably, the support substrate may be prepared by selecting an insulating material whose CTE is consistent with that of the second insulating material of the fine line interconnection layer, or the CTE of the insulating material for preparing the support substrate may be adjusted to be consistent with that of the second insulating material of the fine line interconnection layer. The support substrate may also be prepared by selecting an insulating material whose CTE is consistent with that of the fourth insulating material of the build-up layer, or the CTE of the insulating material for preparing the support substrate may be adjusted to be consistent with that of the fourth insulating material of the build-up layer. The consistency here means that the difference in CTE between the two materials satisfies a desired preset range, which may be specifically set according to requirements and expectations. Since the core layer is disposed between the fine line interconnection layer and the build-up layer, by controlling the CTE of the material for preparing the support substrate of the core layer to be consistent with that of the insulating material of the fine line interconnection layer and/or the build-up layer, the stress between the core layer and the fine line interconnection layer or the build-up layer can be effectively reduced, avoiding defects such as warping of the prepared carrier structure, and increasing the reliability of the carrier structure and the semiconductor device prepared therefrom. In some exemplary embodiments, the support substrate of the core layer 12 is preferably made of a third insulating material, so as to provide electrical isolation between adjacent second electrically conductive structures. The third insulating material may be an insulating material whose thermal expansion coefficient is consistent with that of the second insulating material of the fine line interconnection layer and/or the fourth insulating material of the build-up layer, or the third insulating material is an insulating material with an adjustable thermal expansion coefficient. In an exemplary embodiment, the third insulating material may be a plastic packaging material such as epoxy resin, ceramics, glass, BT resin, or powder capable of low-temperature sintering. Since the CTE of the plastic packaging material is adjustable, preparing the support substrate with the plastic packaging material can realize adjustment of the CTE of the material used to prepare the support substrate according to requirements to be consistent with that of the second insulating material of the fine line interconnection layer and/or the fourth insulating material of the build-up layer. Preferably, the third insulating material is a mixture of plastic packaging material and heat-conducting microspheres. In an exemplary embodiment, it may be a mixture of epoxy resin and heat-conducting microspheres. The heat-conducting microspheres refer to spherical inorganic heat-conducting filler particles with good thermal conductivity and insulation, such as spherical silica particles (also known as silica microspheres), which are used to fill plastic packaging materials such as epoxy resin to obtain epoxy resin composites with specific thermal conductivity or CTE. In this case, the CTE of the third insulating material may be adjusted by adjusting parameters such as the content of the heat-conducting microspheres, the particle size of the selected heat-conducting microspheres, and the type of the selected heat-conducting microspheres, so that it can meet expectations. In some possible embodiments, the third insulating material is a mixture of epoxy resin and silica microspheres. Since the CTE of epoxy resin is about 60*10⁻⁶/° C. and the CTE of silica microspheres is about 0.6*10⁻⁶/° C., representing a large difference therebetween, the CTE of the third insulating material can be adjusted to meet expectations by adjusting the content of silica microspheres. For example, increasing the content of silica microspheres can effectively reduce the CTE of the third insulating material and increase its modulus of elasticity, but will reduce the viscosity of the third insulating material and reduce its hot-melt fluidity. Therefore, the CTE of the third insulating material can be adjusted to a desired range according to needs and expectations, such as being adjusted to be consistent with the thermal expansion coefficient of the second insulating material of the fine line interconnection layer and/or the fourth insulating material of the build-up layer, so as to manufacture a higher-quality carrier structure. In some preferred embodiments, the third insulating material may be an insulating material whose CTE ranges from 2-20*10⁻⁶/° C., or the CTE of the third insulating material is adjusted to range from 2-20*10⁻⁶/° C. In an embodiment where the third insulating material is a mixture of plastic packaging material and heat-conducting microspheres, a mass fraction range of the heat-conducting microspheres is preferably 60-99 w.t %, so that the modulus of elasticity, viscosity and hot-melt fluidity of the obtained third insulating material all meet packaging requirements.

In some possible embodiments, the build-up layer 13 includes multiple third internal interconnection lines 131 being electrically conductive and at least one third electrically conductive structure 134 electrically connected to the first internal interconnection lines of the pin interconnection layer 10 and the second internal interconnection lines of the fine line interconnection layer 11. The number of the third internal interconnection lines, and the number and positions of the third electrically conductive structures may be set according to requirements. The third internal interconnection lines in the build-up layer 13 are preferably interconnection lines made of a conductive material such as metal, preferably copper, silver or gold. The third electrically conductive structures in the build-up layer 13 may be exemplarily contact points, conductive columns, or conductive vias. In a preferred embodiment, the third electrically conductive structures in the build-up layer 13 are in one-to-one correspondence with the second electrically conductive structures in the core layer 12 in terms of quantity and position, and are electrically connected to the second electrically conductive structures, so that the third internal interconnection lines in the build-up layer 13 can be electrically conducted with the first internal interconnection lines in the pin interconnection layer 10 and the second internal interconnection lines in the fine line interconnection layer 11 via the second electrically conductive structures in the core layer 12. In other embodiments, it is also possible to dispose third internal interconnection lines in one-to-one correspondence with the second electrically conductive structures of the core layer 12 on the build-up layer 13 adjacent to the core layer 12 (i.e., contact points of at least part of the third internal interconnection lines in the build-up layer adjacent to the core layer 12 are disposed at the positions of the second electrically conductive structures of the core layer 12), and dispose in other build-up layers 13 third electrically conductive structures and third internal interconnection lines electrically connected to the third internal interconnection lines in the build-up layer 13 adjacent to the core layer 12, so as to realize the electrical connection between the build-up layer 13 and the pin interconnection layer 10 and the fine line interconnection layer 11. In some exemplary embodiments, the outermost build-up layer 13 further includes at least one BGA opening 133 for BGA ball planting. The BGA openings are disposed at corresponding positions of at least part of the third internal interconnection lines or their contact points in the outermost build-up layer 13. The number of the BGA openings may be designed according to requirements. It should be noted that BGA (Ball Grid Array, also known as BGA ball) is used to provide pin interfaces connected with external devices. For example, the external device may be a CPU, a GPU, an ASIC (Application Specific Integrated Circuit), etc. In some exemplary embodiments, the build-up layer 13 further includes a fourth insulating material 132 for providing electrical isolation between adjacent third internal interconnection lines being electrically conductive and/or third electrically conductive structures. The fourth insulating material may be an organic material such as epoxy resin, BT (Bismaleimide Triazine), or polyimide. The outermost build-up layer refers to the build-up layer farthest away from the core layer 12 in the direction away from the core layer 12, and is exposed on the outer surface of the carrier structure 100 to be connected with external devices. The innermost build-up layer refers to the build-up layer adjacent to the core layer 12.

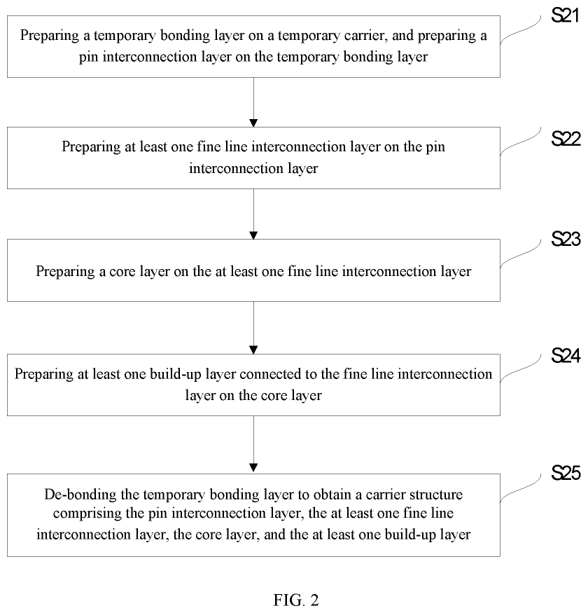

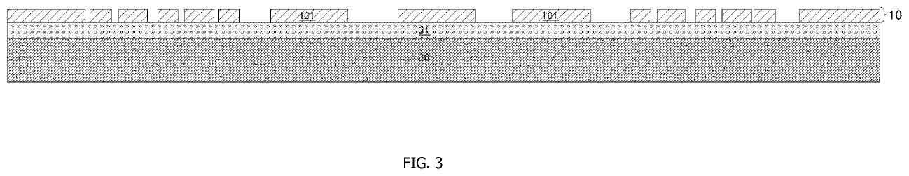

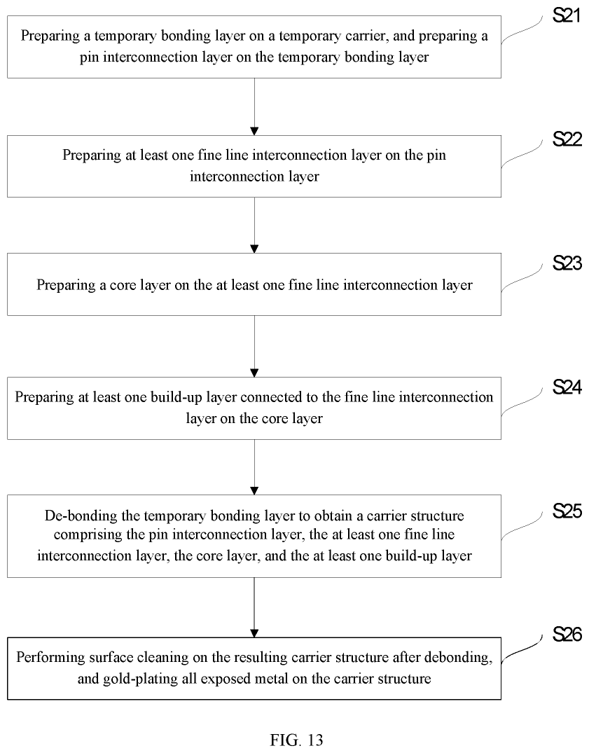

The method for preparing the carrier structure with the above structure will be described in detail hereinafter with reference to FIGS. 2 to 13. FIG. 2 schematically depicts a process flow of a method for manufacturing a carrier structure suitable for chiplet fine lines in some embodiments. FIGS. 3-12 schematically show a process flow of manufacturing the carrier structure with the above features by using the method shown in FIG. 2. FIG. 13 schematically depicts a flow of a method for manufacturing a carrier structure suitable for chiplet fine lines in other embodiments.

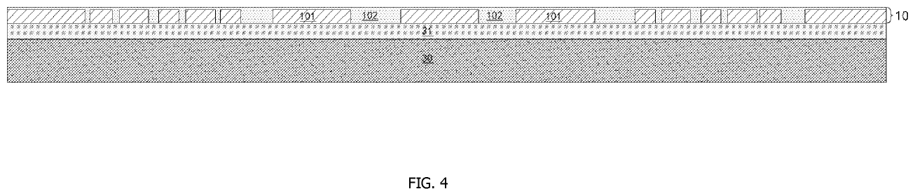

As shown in FIG. 2, in some embodiments, the method for manufacturing a carrier structure suitable for chiplet fine lines includes an operation S21, including preparing a temporary bonding layer on a temporary carrier, and preparing a pin interconnection layer on the temporary bonding layer. In some exemplary embodiments, the temporary carrier may be a glass carrier, a ceramic carrier, a silicon chip, a metal carrier, etc. The temporary bonding layer is configured to be removable by pyrolytic or photolytic bonding. In an exemplary embodiment, the temporary bonding layer may be formed by coating a temporary bonding material on the temporary carrier. The temporary bonding material may be a pyrolytic bonding film, a photolytic bonding film, or the like. In some possible embodiments, the pin interconnection layer may be prepared on the temporary bonding layer by using a semi-additive method. FIG. 3 correspondingly shows a vertical cross-sectional view of a carrier structure obtained by preparing the pin interconnection layer 10 on the temporary bonding layer 31 in some embodiments. As shown in FIG. 3, the temporary bonding layer 31 is disposed on the temporary carrier 30, the pin interconnection layer 10 is disposed on the temporary bonding layer 31 and includes a plurality of first internal interconnection lines 101 being electrically conductive. FIG. 4 correspondingly shows a vertical cross-sectional view of a carrier structure obtained by preparing the pin interconnection layer 10 on the temporary bonding layer 31 in other embodiments. As shown in FIG. 4, in other embodiments, the pin interconnection layer 10 further includes a first insulating material 102 for providing electrical isolation between adjacent first internal interconnection lines 101 being electrically conductive.

In an exemplary embodiment, preparing the pin interconnection layer on the temporary bonding layer by using the semi-additive method can specifically be implemented as follows. In a first step, a seed layer metal is sputtered. In a second step, a dry film is laminated and then exposed, developed and patterned. In a third step, the metal of a required pattern is electroplated. In the last step, excess metal is etched to complete the preparation of the pin interconnection layer.

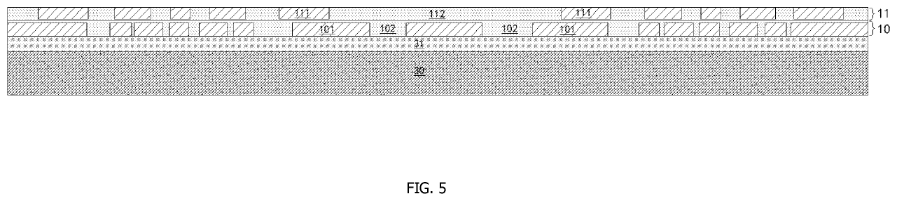

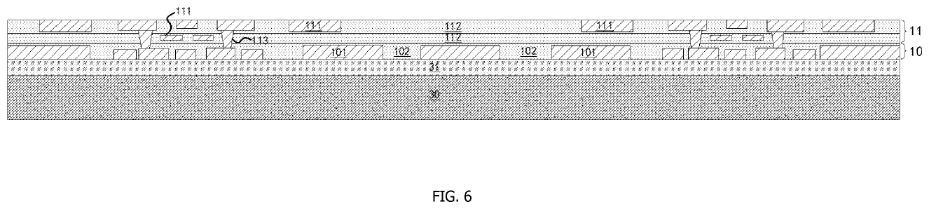

As shown in FIG. 2, in some embodiments, the method for manufacturing a carrier structure suitable for chiplet fine lines further includes an operation S22, including preparing at least one fine line interconnection layer on the pin interconnection layer. In some possible embodiments, the fine line interconnection layer may be prepared on the pin interconnection layer by a redistribution process (also called RDL technology). The fine line interconnection layer prepared on the pin interconnection layer may be a single layer in some exemplary embodiments, and may be two or more layers in other embodiments. FIG. 5 correspondingly shows a vertical cross-sectional view of a carrier structure obtained after preparing one fine line interconnection layer in some embodiments. As shown in FIG. 5, the temporary bonding layer 31 is disposed on the temporary carrier 30, the pin interconnection layer 10 is disposed on the temporary bonding layer 31, and one fine line interconnection layer 11 is disposed on the pin interconnection layer 10. The fine line interconnection layer 11 includes a plurality of second internal interconnection lines 111 being electrically conductive and a second insulating material 112 for providing electrical isolation between adjacent second internal interconnection lines 111 being electrically conductive. FIG. 6 correspondingly shows a vertical cross-sectional view of a carrier structure obtained after preparing two fine line interconnection layers in other embodiments. As shown in FIG. 6, in other embodiments, two fine line interconnection layers 11 are disposed on the pin interconnection layer 10, and each fine line interconnection layer 11 includes a plurality of second internal interconnection lines 111 being electrically conductive and a second insulating material 112 for electrical isolation between adjacent second internal interconnection lines 111 being electrically conductive. At least one first electrically conductive structure 113 capable of electrically conducting with the first internal interconnection lines 101 in the pin interconnection layer 10 is also included in the prepared second fine line interconnection layer 11.

In an exemplary embodiment, the preparation of each fine line interconnection layer by using a rewiring process may specifically include the following steps. In a first step, a photosensitive dry film is laminated, and opening areas in a first electrically conductive structure required are exposed and developed. In a second step, a metal seed layer is sputtered. In a third step, a photosensitive dry film is laminated, and the first internal interconnection line areas required are exposed and developed. In a fourth step, the first internal interconnection lines are electroplated. In the last step, excess metal is removed by etching to complete the preparation of a single-layer fine line interconnection layer.

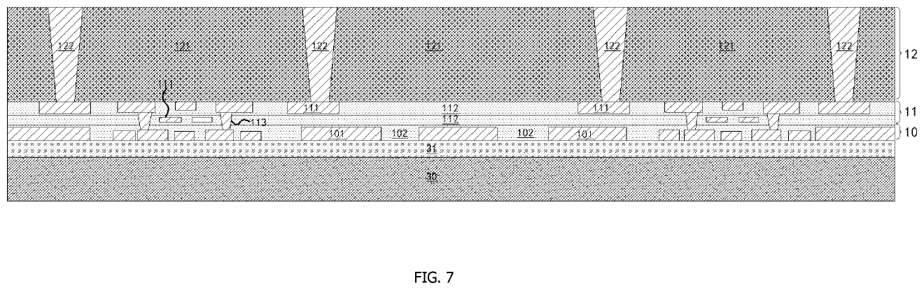

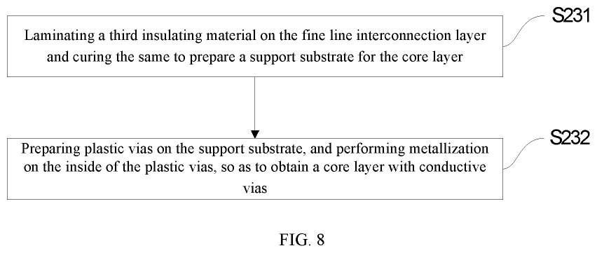

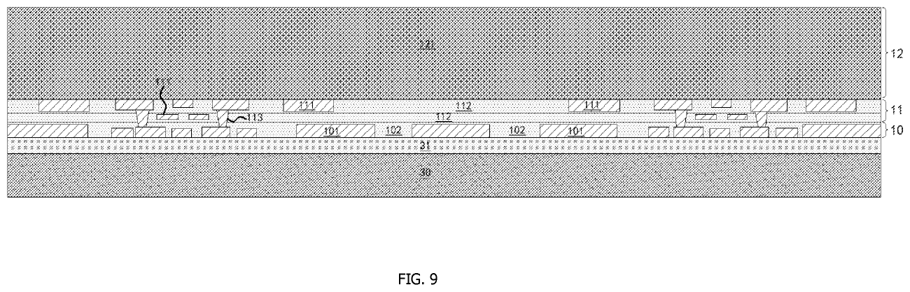

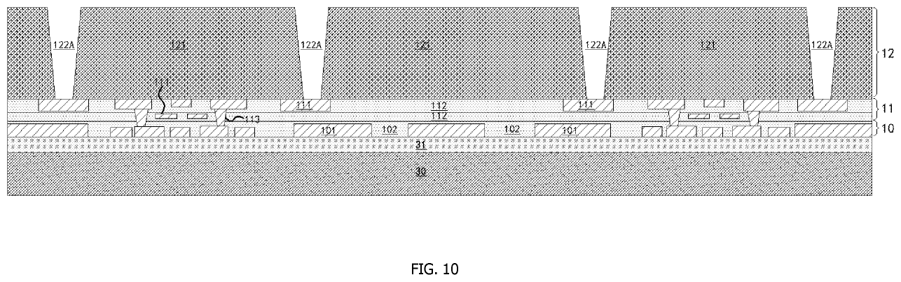

As shown in FIG. 2, in some embodiments, the method for manufacturing a carrier structure suitable for chiplet fine lines further includes an operation S23, including preparing a core layer on the at least one fine line interconnection layer. FIG. 7 shows a vertical cross-sectional view of a carrier structure obtained after preparing the core layer in some embodiments. As shown in FIG. 7, the temporary bonding layer 31 is disposed on the temporary carrier 30, the pin interconnection layer 10 is disposed on the temporary bonding layer 31, two fine line interconnection layers 11 are disposed on the pin interconnection layer 10, and the core layer 12 is disposed on the prepared second fine line interconnection layer 111. The core layer 12 includes a support substrate 121 and a plurality of second electrically conductive structures 122 capable of being electrically conducted with the second internal interconnection lines 111 of the fine line interconnection layer 11. The second electrically conductive structures 122 formed in the core layer 12 are conducting vias. FIG. 8 shows some possible embodiments of operation S23. Taking the second electrically conductive structures as conductive vias and the third insulating material as a plastic packaging material as an example, as shown in FIG. 8, in some possible embodiments, operation S23 may include a process S231, including laminating a third insulating material on the fine line interconnection layer and curing the same to prepare a support substrate for the core layer. Preferably, the process S231 is to hot-press the plastic packaging material on the prepared uppermost fine line interconnection layer, and to perform oxygen-barrier heating and curing on the carrier structure hot-pressed with the plastic packaging material to prepare a support substrate for the core layer. FIG. 9 correspondingly shows a vertical cross-sectional view of a carrier structure obtained after preparing the support substrate of the core layer in some embodiments. As shown in FIG. 9, after hot pressing and curing, the support substrate 121 is formed on the second fine line interconnection layer 11 to provide mechanical support for the fine line interconnection layer 11 and improve the mechanical strength, reliability and manufacturability of the entire carrier structure. The thickness of the support substrate can characterize the internal stress and mechanical strength of the core layer, which can in turn affect the preparation yield of the fine line interconnection layer and can reflect the mechanical strength and reliability of the prepared carrier structure. Therefore, in some possible embodiments, in process S231, the thickness of the support substrate can be adjusted according to requirements to improve the manufacturability of the carrier structure. Preferably, the thickness of the support substrate can be adjusted according to the application scene. In an exemplary embodiment, the thickness of the support substrate may be set from 50 to 1000 μm. Further, as shown in FIG. 8, operation S23 may also include a process S232, including preparing plastic vias on the support substrate, and performing metallization on the inside of the plastic vias, so as to obtain a core layer with conductive vias. FIG. 10 correspondingly shows a vertical cross-sectional view of a carrier structure obtained after the plastic vias are prepared on the support substrate in some embodiments. As shown in FIG. 10, a plurality of plastic vias 122A are disposed on the support substrate 121 at positions corresponding to at least part of the second internal interconnection lines 111 of the fine line interconnection layer 11, so as to expose at least part of the second internal interconnection lines 111 of the fine line interconnection layer 11 through the plastic vias 122A. After the plastic vias are metallized, the carrier structure shown in FIG. 7 may be obtained. Therefore, by performing metallization on the plastic vias 122A, the plastic vias 122A may be set as second electrically conductive structures 122 in the form of conductive vias to enable the core layer 12 to be electrically connected to the corresponding part of the second internal interconnection lines 111 of the fine line interconnection layer 11 through the conductive vias. In an exemplary embodiment, in process S232, plastic vias may be prepared on the third insulating material such as a plastic packaging material by a laser drilling process, a mechanical hole transfer process, or a plasma etching process, and the inside of the plastic vias may be metallized by electroplating after sputtering a seed layer or sintering after filling the vias with nanomaterials.

In a preferred embodiment, when preparing the core layer, the characteristics of the third insulating material for preparing the support substrate may also be used to achieve the goal of controlling the yield of the fine line interconnection layer and the reliability of the carrier structure through the core layer. As a preferred embodiment, the CTE (thermal expansion coefficient) of the third insulating material for preparing the support substrate may be used to achieve the goal of controlling the yield of the fine line interconnection layer and the reliability of the carrier structure through the core layer. Preferably, the support substrate may be prepared by selecting a third insulating material whose CTE is consistent with that of the second insulating material of the fine line interconnection layer, or the CTE of the third insulating material for preparing the support substrate may be adjusted to be consistent with that of the second insulating material of the fine line interconnection layer. A third insulating material whose CTE is consistent with that of the fourth insulating material of the build-up layer may also be selected to prepare the support substrate, or the CTE of the third insulating material for preparing the support substrate may be adjusted to be consistent with that of the fourth insulating material of the build-up layer. The consistency here refers to that the difference of the CTE satisfies a desired preset range, which may be specifically set according to requirements and expectations. In some exemplary embodiments, the third insulating material may be an insulating material whose thermal expansion coefficient is consistent with that of the second insulating material of the fine line interconnection layer and/or the fourth insulating material of the build-up layer, or the third insulating material may an insulating material with an adjustable thermal expansion coefficient. In an exemplary embodiment, the third insulating material may be a plastic packaging material such as epoxy resin, ceramics, glass, BT resin, or powder capable of low-temperature sintering. Preferably, the third insulating material is a mixture of plastic packaging material and heat-conducting microspheres. In an exemplary embodiment, it may be a mixture of epoxy resin and heat-conducting microspheres. In this case, by adjusting parameters such as the content of the heat-conducting microspheres, the particle size of the selected heat-conducting microspheres and the type of the heat-conducting microspheres selected, the CTE of the third insulating material can be adjusted to meet expectations. For example, the CTE of the third insulating material is adjusted to be between 2-20*10⁻⁶/° C. In a preferred embodiment, a mass fraction of the heat-conducting microspheres in the mixture may be set in the range from 60 to 99 w.t %, so that the elastic modulus, viscosity and hot-melt fluidity of the obtained third insulating material all meet the packaging requirements. As a possible embodiment, the third insulating material is a mixture of epoxy resin and silica microspheres. In other embodiments, an insulating material whose CTE is between 2-20*10⁻⁶/° C. may also be directly selected as the third insulating material. Therefore, when the core layer is prepared on the fine line interconnection layer by hot-press and plastic packaging, a suitable laminating stress may be applied to the fine line interconnection layer by controlling the CTE of the third insulating material, so that the core layer and the fine line interconnection layer may be better connected together, thereby providing the desired mechanical strength for the transfer of the fine line interconnection layer, increasing the line yield and manufacturability of the final prepared fine line interconnection layer, and improving the reliability of the carrier structure.

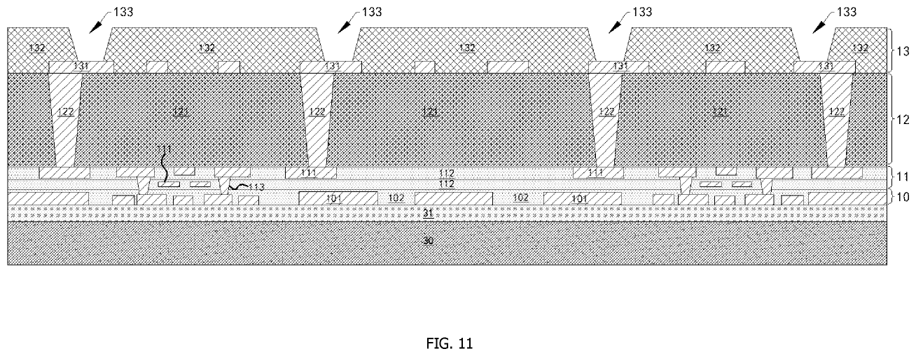

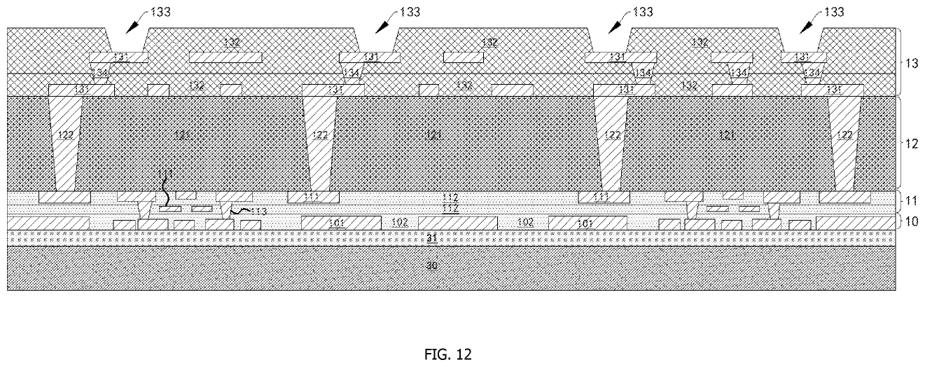

As shown in FIG. 2, in some embodiments, the method for manufacturing a carrier structure suitable for chiplet fine lines further includes an operation S24, including preparing at least one build-up layer connected to the fine line interconnection layer on the core layer. In some possible embodiments, third internal interconnection lines of the build-up layer may be prepared at the second electrically conductive structures of the core layer, so that the build-up layer can be electrically connected with other layers (such as the fine line interconnection layer). In some preferred embodiments, BGA openings for BGA ball planting may also be formed by opening at contact points of at least part of the third internal interconnection lines of the outermost build-up layer. In an exemplary embodiment, etching can be performed at the contact points of the desired third internal interconnection lines to form the BGA openings. The build-up layer prepared on the core layer may be a single layer in some embodiments, and may be two or more layers in other embodiments. FIG. 11 correspondingly shows a vertical cross-sectional view of a carrier structure obtained after preparing one build-up layer in some embodiments. As shown in FIG. 11, the temporary bonding layer 31 is disposed on the temporary carrier 30, the pin interconnection layer 10 is disposed on the temporary bonding layer 31, two fine line interconnection layers 11 are disposed on the pin interconnection layer 10, the core layer 12 is disposed on the fine line interconnection layer 11, and a build-up layer 13 is disposed on the core layer 12. The build-up layer 13 includes a plurality of third internal interconnection lines 131 being electrically conductive and a fourth insulating material 132 for providing electrical isolation between adjacent third internal interconnection lines 131 being electrically conductive. Contact points of at least part of the third internal interconnection lines 131 of the build-up layer 13 are provided with BGA openings 133 facing away from the core layer 12. The core layer 12 is provided with second electrically conductive structures 122 in the shape of conductive vias. At least part of the third internal interconnection lines 131 of the build-up layer 13 are disposed in a one-to-one correspondence with the second electrically conductive structures 122 of the core layer 12, which are disposed in one-to-one correspondence with at least part of the second internal interconnection lines 111 in the fine line interconnection layer 11, thereby enabling the build-up layer 13 and the fine line interconnection layer 11 to be electrically interconnected. FIG. 12 correspondingly shows a vertical cross-sectional view of a carrier structure obtained after preparing two build-up layers in other embodiments. As shown in FIG. 12, in other embodiments, two build-up layers 13 are disposed on the core layer 12. Each build-up layer 13 includes a plurality of third internal interconnection lines 131 being electrically conductive and a fourth insulating material 132 for providing electrical isolation between adjacent third internal interconnection lines 131 being electrically conductive. The prepared second build-up layer 13 (that is, the outermost build-up layer) also includes at least one third electrically conductive structure 134 capable of being electrically conducted with the third internal interconnection lines 131 in the first build-up layer 13. BGA openings 133 are disposed on the outermost layer, that is, the build-up layer produced at the second time.

As an exemplary embodiment, the preparation of each build-up layer may include the following steps. In a first step, a photosensitive dry film is laminated, and an opening area of a desired third electrically conductive structure is exposed and developed. In a second step, a metal seed layer is sputtered in the opening area of the third electrically conductive structure. In a third step, a photosensitive dry film is laminated, and a desired third internal interconnection line area is exposed and developed. In a fourth step, metal lines are electroplated in the third internal interconnection line area. In a fifth step, excess metal is removed by etching to form a single-layer build-up layer.

As shown in FIG. 2, in some embodiments, the method for manufacturing a carrier structure suitable for chiplet fine lines further includes an operation S25, including debonding the temporary bonding layer to obtain a carrier structure including the pin interconnection layer, the at least one fine line interconnection layer, the core layer, and the at least one build-up layer. In operation S25, the temporary bonding layer may be debonded using a corresponding debonding method according to the selected temporary bonding material. In some embodiments, after the process of operation S25, the carrier structure 100 finally obtained is the same as the carrier structure shown in FIG. 1. In other embodiments, the number of the fine line interconnection layers and the number of the build-up layers of the carrier structure, the number of the BGA openings, the number of the second electrically conductive structures of the core layer, the number of internal interconnection lines of the build-up layer, the number of internal interconnection lines of the fine line interconnection layer, and the number of internal interconnection lines of the pin interconnection layer, etc. may be adaptively adjusted according to needs and expectations to obtain a correspondingly structured carrier structure.

In other possible embodiments, as shown in FIG. 13, on the basis of the process shown in FIG. 2, the method for manufacturing a carrier structure suitable for chiplet fine lines may further include an operation S26, including performing surface cleaning on the carrier structure obtained after debonding and gold-plating all exposed metal on the carrier structure. In other embodiments, after operation S26, the obtained carrier structure may also be cut according to requirements, so as to obtain a carrier structure having the desired size.

The application of the above carrier structure will be described in detail below.

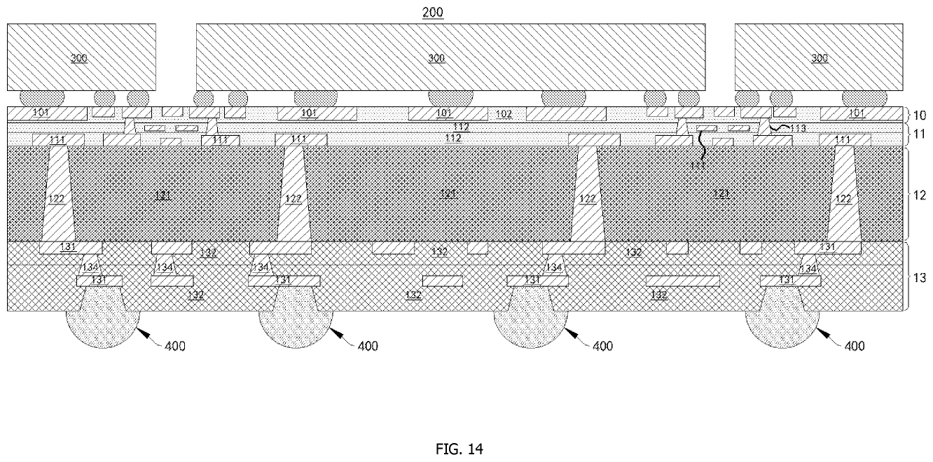

As one of the possible application methods, the above carrier structure may be applied to the packaging of chiplets to obtain a fine line chiplet packaging structure. FIG. 14 schematically shows a fine line chiplet packaging structure 200 in some embodiments. As shown in FIG. 14, it includes the carrier structure 100 shown in FIG. 1 and at least one chip 300 bonded to a second side of the pin interconnection layer 10 of the carrier structure 100, which may be a plurality of chips that realize specific functions that meet expectations. The specific functions and the number of the chips to be bonded may be selected according to requirements. In an exemplary embodiment, the bonded chip may be a processor chip, a memory chip, a sensor chip, or a passive device chip, etc. according to the required functions. According to requirements, in a specific application, a plurality of chips with the same function may be bonded on the carrier structure 100, or a plurality of chips with different functions may be bonded on the carrier structure 100, so as to obtain a chiplet packaging structure with the desired function.

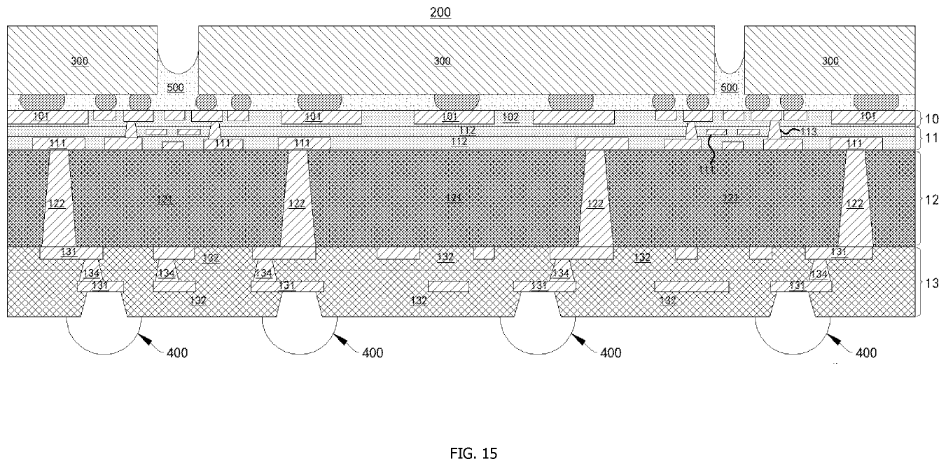

FIG. 15 schematically shows a fine line chiplet packaging structure 200 in other embodiments. In some preferred embodiments, the packaging structure 200 is also provided with a plastic packaging protection layer 500 for fixing and protecting the chip 300 bonded to the second side of the pin interconnection layer 10 of the carrier structure 100. In an exemplary embodiment, the plastic packaging protection layer 500 is disposed between the chip 300 and the second side of the pin interconnection layer 10, or disposed between the chip 300 and the second side of the pin interconnection layer 10 and between the chips 300, or disposed to cover at least a partial area of the chip 300.

In some possible embodiments, as shown in FIGS. 14 and 15, the packaging structure 200 further includes at least one BGA ball 400 disposed at the BGA openings in the build-up layer of the carrier structure. The number of the BGA balls may be set according to requirements. The packaging structure 200 may be connected with required external devices through the BGA balls 400 to realize desired device functions.

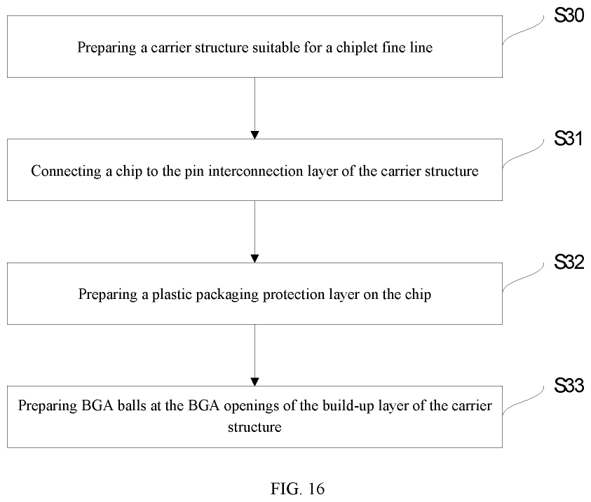

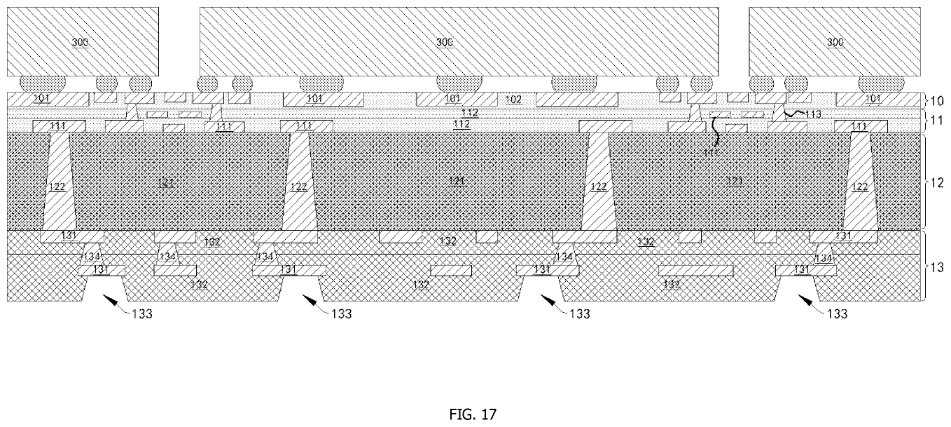

The method for manufacturing a fine line chiplet packaging structure by using the above carrier structure will be described hereinafter. FIG. 16 schematically shows a flow of a method for manufacturing a fine line chiplet packaging structure in a possible embodiment. As shown in FIG. 16, the method includes an operation 30 of preparing a carrier structure suitable for a chiplet fine line. For the specific content of operation 30, reference may be made to the corresponding description in the above method for manufacturing a carrier structure. After operation 30, the method according to the embodiment of the present invention further includes an operation 31, including connecting a chip to the pin interconnection layer of the carrier structure. In some possible embodiments, in operation 31, the chip may be first attached to the pin interconnection layer of the carrier structure, and then bonded to the pin interconnection layer of the carrier structure by hot reflow or hot pressing. FIG. 17 correspondingly shows a vertical cross-sectional view of the packaging structure obtained after the chip is bonded to the carrier structure in some embodiments. As shown in FIG. 17, three chips 300 are bonded on the pin interconnection layer 10, in which each chip 300 is connected to contact points of the corresponding exposed first internal interconnection lines of the pin interconnection layer 10 according to its interface characteristics. In other embodiments, the method for manufacturing a fine line chiplet packaging structure further includes an operation 32, including preparing a plastic packaging protection layer on the chip. In operation 32, the plastic packaging protection layer may be prepared by adding an underfill material at the bottom of the chip and heating and curing the same. In other embodiments, the position where the underfill material is added may also be adjusted according to requirements to be between the chip and the pin interconnection layer of the carrier structure and between the chips. In an exemplary embodiment, the underfill added at the bottom of the chip may be any one or a combination of two or more of capillary underfill (CUF), non-flow underfill (NUF) and wafer-level underfill (WLUF).

As shown in FIG. 16, in some embodiments, the method for manufacturing a fine line chiplet packaging structure further includes an operation 33, including preparing BGA balls at the BGA openings of the build-up layer of the carrier structure, such as by performing metal pad ball planting to obtain a packaging structure with BGA balls. Taking the plastic packaging layer being provided on the chip as an example, the packaging structure obtained using the method shown in FIG. 16 may be as shown in FIG. 15. In other possible embodiments, the number of the chips on the packaging structure, the number of internal interconnection lines in the carrier structure, the positions and the number of the BGA openings, and the number of the build-up layers and the number of the fine line interconnection layers in the carrier structure may be changed according to the requirements to make the packaging structure obtained meet the requirements.

Finally, it should be noted that the above embodiments are only used to illustrate technical solutions of the present application rather than making an limitation thereto. Although the present application has been described in detail with reference to the foregoing embodiments, those of ordinary skill in the art should understand that modifications can be made to the technical solutions described in the foregoing embodiments, or equivalent replacements can be made to some of the technical features. These modifications or replacements do not make the essence of the corresponding technical solutions deviate from the spirit and scope of the technical solutions of the various embodiments of the present application.

What is claimed is:

1. A method for manufacturing a carrier structure suitable for chiplet fine lines, comprising:
preparing a temporary bonding layer on a temporary carrier, and preparing a pin interconnection layer on the temporary bonding layer;
preparing at least one fine line interconnection layer on the pin interconnection layer;
preparing a core layer on the at least one fine line interconnection layer, wherein the core layer is formed with a second electrically conductive structure interconnected with the at least one fine line interconnection layer and/or the pin interconnection layer;
preparing at least one build-up layer connected to the fine line interconnection layer on the core layer, wherein BGA openings are formed in an outermost build-up layer; and
de-bonding the temporary bonding layer to obtain the carrier structure comprising the pin interconnection layer, the at least one fine line interconnection layer, the core layer, and the at least one build-up layer.

2. The method according to claim 1, further comprising:
performing surface cleaning on the obtained carrier structure after the de-bonding, and gold-plating all exposed metal on the carrier structure.

3. The method according to claim 1, wherein the pin interconnection layer comprises a first insulating material and at least one first internal interconnection line, each first internal interconnection line has a line width between 2 μm and 200 μm, and any two adjacent first internal interconnection lines have a line spacing therebetween between 2 μm and 200 μm.

4. The method according to claim 1, wherein each fine line interconnection layer comprises a second insulating material and at least one second internal interconnection line, each second internal interconnection line has a line width between 0.1 μm and 10 μm, and any two adjacent second internal interconnection lines have a line spacing therebetween between 0.1 μm and 10 μm.

5. The method according to claim 1, wherein each build-up layer comprises a fourth insulating material and at least one third internal interconnection line, at least parts of the third internal interconnection lines of the build-up layer adjacent to the core layer are disposed at the second electrically conductive structure of the core layer, and the BGA openings are disposed at contact points of at least parts of the third internal interconnection lines of the outermost build-up layer.

6. The method according to claim 4, wherein the core layer comprises a support substrate made of a third insulating material, and each build-up layer comprises a fourth insulating material; the third insulating material is an insulating material whose thermal expansion coefficient is consistent with that of the second insulating material of the fine line interconnection layer and/or the fourth insulating material of the build-up layer; or, the third insulating material is an insulating material whose thermal expansion coefficient is adjustable; and
preferably, the thermal expansion coefficient of the third insulating material is between 2*10⁻⁶/° C. and 20*10⁻⁶/° C. or is adjustable to be between 2*10⁻⁶/° C. and 20*10⁻⁶/° C.

7. The method according to claim 6, wherein a thickness of the support substrate is determined based on requirements of an application scene to which the prepared carrier structure is applicable, and is preferably set between 50 μm and 1000 μm.

8. The method according to claim 6, wherein the third insulating material is a plastic packaging material such as epoxy resin, ceramics, glass, BT resin, or powder capable of low-temperature sintering; or, the third insulating material is a mixture of plastic packaging material and heat-conducting microspheres, preferably a mixture of epoxy resin and heat-conducting microspheres, and a mass fraction range of the heat-conducting microspheres is preferably 60 w.t %-99 w.t %.

9. The method according to claim 6, wherein the first insulating material, the second insulating material and the fourth insulating material are all organic materials, preferably epoxy resin, BT, or polyimide.

10. A method for manufacturing a fine line chiplet packaging structure, comprising:
preparing the carrier structure comprising the pin interconnection layer, the at least one fine line interconnection layer, the core layer, and the at least one build-up layer by using the method according to claim 1;
connecting at least one chip to the pin interconnection layer of the carrier structure;
preparing a plastic packaging protection layer on the chip; and
preparing BGA balls at BGA openings of the build-up layer of the carrier structure.

11. The method according to claim 10, wherein the chip is any one of a processor, a memory, a sensor, or a passive device.

12. A carrier structure suitable for chiplet fine lines, comprising:
a pin interconnection layer;
at least one fine line interconnection layer disposed on a first side of the pin interconnection layer;
a core layer disposed on a side of the at least one fine line interconnection layer away from the pin interconnection layer, wherein a second electrically conductive structure is formed in the core layer, and the core layer is interconnected with the at least one fine line interconnection layer and/or the pin interconnection layer through the second electrically conductive structure; and
at least one build-up layer disposed on a side of the core layer away from the at least one fine line interconnection layer, wherein the at least one build-up layer is connected with the fine line interconnection layer through the second electrically conductive structure, and BGA openings are formed in an outermost build-up layer.

13. The carrier structure according to claim 12, wherein the pin interconnection layer comprises a first insulating material and at least one first internal interconnection line, each first internal interconnection line has a line width between 2 μm and 200 μm, and any two adjacent first internal interconnection lines have a line spacing therebetween between 2 μm and 200 μm.

14. The carrier structure according to claim 12, wherein each fine line interconnection layer comprises a second insulating material and at least one second internal interconnection line, each second internal interconnection line has a line width between 0.1 μm and 10 μm, and any two adjacent second internal interconnection lines have a line spacing therebetween between 0.1 μm and 10 μm.

15. The carrier structure according to claim 12, wherein each build-up layer comprises a fourth insulating material and at least one third internal interconnection line, at least parts of the third internal interconnection lines of the build-up layer adjacent to the core layer are disposed at the second electrically conductive structure of the core layer, and the BGA openings are disposed at contact points of at least parts of the third internal interconnection lines of the outermost build-up layer.

16. The carrier structure according to claim 14, wherein the core layer comprises a support substrate made of a third insulating material;
the third insulating material is an insulating material whose thermal expansion coefficient is consistent with that of the second insulating material of the fine line interconnection layer and/or the fourth insulating material of the build-up layer; or, the third insulating material is an insulating material whose thermal expansion coefficient is adjustable; and
preferably, the thermal expansion coefficient of the third insulating material is between 2*10⁻⁶/° C. and 20*10⁻⁶/° C. or is adjustable to be between 2*10⁻⁶/° ° C. and 20*10⁻⁶/° C.

17. The carrier structure according to claim 16, wherein a thickness of the support substrate is determined based on requirements of an application scene to which the prepared carrier structure is applicable, and is preferably set between 50 μm and 1000 μm.

18. The carrier structure according to claim 16, wherein the third insulating material is a plastic packaging material such as epoxy resin, ceramics, glass, BT resin, or powder capable of low-temperature sintering; or, the third insulating material is a mixture of plastic packaging material and heat-conducting microspheres, preferably a mixture of epoxy resin and heat-conducting microspheres, and a mass fraction range of the heat-conducting microspheres is preferably 60 w.t %-99 w.t %.

19. A fine line chiplet packaging structure, comprising:
the carrier structure according to claim 12;
at least one chip bonded to a second side of the pin interconnection layer of the carrier structure;
a plastic packaging protection layer disposed on the chip; and
BGA balls disposed at the BGA openings.

20. The packaging structure according to claim 19, wherein the chip is any one of a processor, a memory, a sensor, or a passive device.
